(19) United States
(12) Patent Application Publication
(10) Pub. No.: US 2024/0371718 A1
(43) Pub. Date: Nov. 7, 2024

(54) SEMICONDUCTOR PACKAGE INCLUDING HEAT DISSIPATION STRUCTURE

(71) Applicant: Samsung Electronics Co., Ltd., Suwon-si (KR)

(72) Inventors: Daehan YOUN, Suwon-si (KR); Youngsang CHO, Suwon-si (KR); Kyoung-Min LEE, Suwon-si (KR); Junho HUH, Suwon-si (KR)

(73) Assignee: Samsung Electronics Co., Ltd., Suwon-si (KR)

(21) Appl. No.: 18/507,369

(22) Filed: Nov. 13, 2023

(30) Foreign Application Priority Data
May 4, 2023 (KR) 10-2023-0058643

(51) Int. Cl. H01L 23/36; H01L 23/00; H01L 23/31; H01L 23/48; H01L 23/498; H01L 25/065

(52) U.S. Cl. CPC H01L 23/36; H01L 23/3128; H01L 23/481; H01L 23/49816; H01L 23/49822; H01L 24/16; H01L 25/0657; H01L 2224/16145; H01L 2224/16227

(57) ABSTRACT

A semiconductor package includes a first package substrate including a first redistribution layer, at least one semiconductor chip disposed on the first redistribution layer and including a semiconductor device, and a second package substrate disposed on the at least one semiconductor chip and including a second redistribution layer. The at least one semiconductor chip includes at least one heat dissipation via having one end adjacent to the semiconductor device and penetrating through at least a portion of the at least one semiconductor chip, and another end contacting the second package substrate. The at least one heat dissipation via is a dissipation path of heat generated from the semiconductor device.

### CROSS-REFERENCE TO RELATED APPLICATION(S)

This application claims benefit of priority to Korean Patent Application No. 10-2023-0058643, filed on May 4, 2023, in the Korean Intellectual Property Office, the disclosure of which is incorporated herein by reference in its entirety.

### BACKGROUND

The present disclosure relates to semiconductor packages, and more particularly to semiconductor packages including a heat dissipation structure.

As storage capacity of semiconductor chips has been recently increased, semiconductor packages including semiconductor chips are required to be small, thin, and lightweight. Research into semiconductor packages including semiconductor chips having various functions and high-speed driving of the semiconductor chips is ongoing. In addition, semiconductor packages may have a package-on-package (POP) structure in which heat generated in a semiconductor chip in each of the packages acts as a thermal resistor while being transferred through a bonding surface between adjacent semiconductor packages. Thus, thermal characteristics of the entire semiconductor package may be deteriorated.

Accordingly, there is demand for a method of, and/or structure for, rapidly removing heat, generated in a semiconductor device in a semiconductor package, from the semiconductor device to maintain reliability of the semiconductor package and to enable smooth operation.

### SUMMARY

Example embodiments provide semiconductor packages having improved heat dissipation characteristics.

Embodiments of the inventive concepts provide a semiconductor package that may include a first package substrate including a first redistribution layer, at least one semiconductor chip disposed on the first redistribution layer and including a semiconductor device, and a second package substrate on the at least one semiconductor chip and including a second redistribution layer. The at least one semiconductor chip includes at least one heat dissipation via as a dissipation path of heat generated from the semiconductor device. The at least one heat dissipation via having one end adjacent to the semiconductor device and penetrating through at least a portion of the at least one semiconductor chip, and another end contacting the second package substrate.

In example embodiments, the another end of the at least one heat dissipation via may be connected to the second redistribution layer.

In example embodiments, the semiconductor package may further include a first connection terminal disposed between the at least one semiconductor chip and the first redistribution layer and connecting the at least one semiconductor chip and the first redistribution layer to each other, and at least one connection structure connecting the first redistribution layer and the second redistribution layer to each other.

In example embodiments, the second redistribution layer may include redistribution lines connected to the at least one connection structure, and a heat dissipation pattern insulated from the redistribution lines, and the at least one heat dissipation via may be connected to the heat dissipation pattern.

In example embodiments, the heat dissipation via may have an upper surface directly contacting a lower surface of the heat dissipation pattern.

In example embodiments, the at least one semiconductor chip may further include a semiconductor substrate on which the semiconductor device is mounted, and the at least one heat dissipation via may penetrate through at least a portion of the semiconductor substate when viewed in plan view.

In example embodiments, the heat dissipation via may have an upper diameter greater than a lower diameter, when viewed in plan view.

In example embodiments, the at least one semiconductor chip may include a first semiconductor chip disposed on the first redistribution layer, and a second semiconductor chip disposed on the first semiconductor chip.

In example embodiments the first semiconductor chip may include a through-via penetrating through at least a portion of the first semiconductor chip, and a first heat dissipation via penetrating through at least a portion of the first semiconductor chip, and the second semiconductor chip may include a second heat dissipation via penetrating through the second semiconductor chip and having one end connected to the first heat dissipation via and another end connected to the redistribution layer.

In example embodiments, the first semiconductor chip may include a first semiconductor substrate and a first semiconductor device provided on the first semiconductor substrate, and the second semiconductor chip may include a second semiconductor substrate and a second semiconductor device provided on the second semiconductor substrate, and the through-via and the first heat dissipation via may penetrate through the first semiconductor substrate, and the second heat dissipation via may penetrate through the second semiconductor substrate.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a plan view of a semiconductor package according to example embodiments of the inventive concepts.

FIG. 2 is a cross-sectional view taken along line A-A′ of FIG. 1.

FIG. 3A is an enlarged cross-sectional view of portion P1 of FIG. 2.

FIGS. 3B and 3C are enlarged cross-sectional views of portion P2 of FIG. 3A.

FIGS. 4A, 4B, 4C and 4D are cross-sectional views corresponding to portion P2 of FIG. 3A and illustrating heat dissipation structures according to various embodiments.

FIGS. 5A, 5B, 5C and 5D are plan views illustrating heat dissipation patterns according to example embodiments, with FIG. 5A illustrating the heat dissipation patterns together with other components and FIGS. 5B to 5D illustrating only the heat dissipation pattern.

FIG. 6 is a simulation graph illustrating thermal resistance in a semiconductor package according to the related art and thermal resistance in a semiconductor package according to example embodiments of the inventive concepts.

FIG. 7 is a cross-sectional view illustrating that a second heat dissipation via is connected to a second lower pad of a semiconductor package substrate, in a semiconductor package according to example embodiments.

FIG. 8 is a cross-sectional view of a semiconductor package according to example embodiments, and illustrates a single semiconductor chip present between a first package substrate and a second semiconductor package.

FIG. 9 is a cross-sectional view of a package-on-package (POP) type package according to example embodiments.

FIG. 10 is a cross-section view illustrating an example of the second semiconductor package of FIG. 9.

FIG. 11 is a block diagram illustrating an electronic system according to example embodiments.

FIG. 12 is a cross-sectional view illustrating a portion of an electronic system in detail.

### DETAILED DESCRIPTION

A semiconductor package according to example embodiments of the inventive concepts may include a heat dissipation structure therein to effectively dissipate heat, generated in a semiconductor chip, through the heat dissipation structure.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, example embodiments will be described with reference to the accompanying drawings.

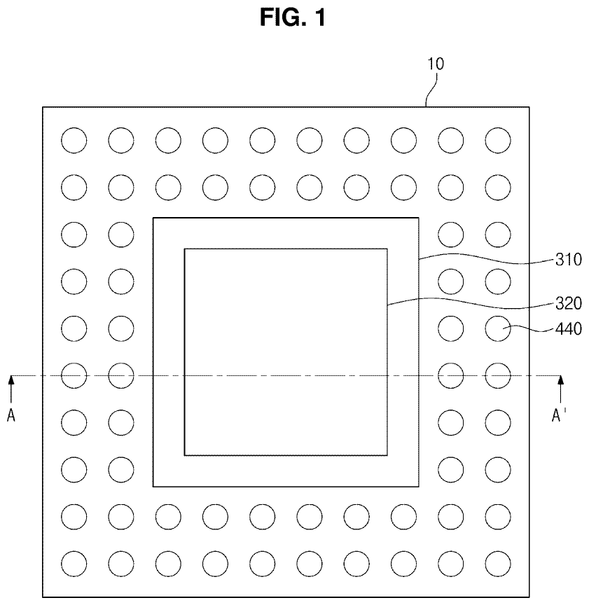

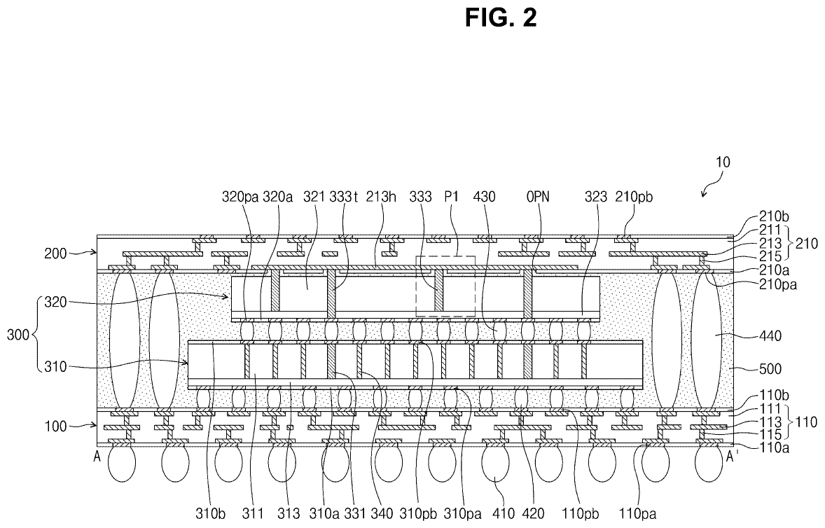

FIG. 1 is a plan view of a semiconductor package according to an example embodiment, and FIG. 2 is a cross-sectional view taken along line A-A′ of FIG. 1.

Referring to FIGS. 1 and 2, the semiconductor package according to example embodiments may include a first package substrate 100, at least one semiconductor chip 300 mounted on the first package substrate 100, and a second package substrate 200.

The first package substrate 100 may include a first redistribution layer 110, a first upper insulating layer 110b disposed above the first redistribution layer 110, and a first lower insulating layer 110a disposed below the first redistribution layer 110. Also, the first package substrate 100 may include first upper pads 110pb exposed by the first upper insulating layer 110b, and first lower pads 110pa exposed by the first lower insulating layer 110a.

The first upper pads 110pb and the first lower pads 110pa may be formed of a conductive material, for example, aluminum (Al), copper (Cu), nickel (Ni), cobalt (Co), zinc (Zn), gold (Au), silver (Ag), platinum (Pt), or alloys thereof.

The first redistribution layer 110 may include a first core layer 111, first redistribution lines 113 disposed on an upper surface and a lower surface of the first core layer 111 and/or inside the first core layer 111 and electrically connecting the first upper pads 110pb and the first lower pads 110pa to each other, and first conductive vias 115 electrically connecting the first redistribution lines 113 to each other.

The first core layer 111 may include at least one selected from phenol resin, epoxy resin, and polyimide. For example, the first core layer 111 may include at least one selected from flame retardant 4 (FR-4), tetrafunctional epoxy, polyphenylene ether, epoxy/polyphenylene oxide, bismaleimide triazine (BT), THERMOUNT® (a nonwoven aramid fiber reinforced substrate for printed wiring boards), cyanate ester, polyimide, and liquid crystal polymer.

The first redistribution lines 113 may include a conductive material such as copper (Cu), aluminum (Al), silver (Ag), tin (Sn), gold (Au), nickel (Ni), lead (Pb), titanium (Ti), or alloys thereof. However, the material of the first redistribution lines 113 is not limited thereto, and the first redistribution lines 113 may include, for example, electrolytically deposited (ED) copper foil, rolled-annealed (RA) copper foil, stainless steel foil, aluminum foil, ultra-thin copper foils, sputtered copper, or copper-alloys.

The first redistribution lines 113 may be disposed on an upper surface and a lower surface of the first core layer 111 and inside the first core layer 111. In example embodiments, the first redistribution lines 113 have been described as being formed in three levels, but example embodiments are not limited thereto. For example, the first redistribution lines 113 may be formed on only an upper surface and a lower surface of the first core layer 111, or may be formed in four or more levels. In example embodiments, among the first redistribution lines 113 disposed in three levels, upper redistribution lines provided in an uppermost level may extend from an upper surface of the first core layer 111. Among the first redistribution lines 113 disposed in three levels, intermediate redistribution lines provided in an intermediate level may extend from the inside of the first core layer 111 in a direction parallel or substantially parallel to the upper surface of the first core layer 111. Lower redistribution lines provided in a lowermost level may extend from the lower surface of the first core layer 111.

In example embodiments, at least a portion of the upper and lower redistribution lines may be appropriately distributed and provided to be connected to the first upper pads 110pb and the first lower pads 110pa.

The first conductive vias 115 are vias connecting the first redistribution lines 113 in a vertical direction, and may be formed to penetrate through at least a portion of the first core layer 111. In some embodiments, the first conductive vias 115 may include a conductive material, for example, a metal such as copper, nickel, stainless steel, molybdenum, manganese, cobalt, tin, magnesium, rhenium, beryllium, gallium, or ruthenium, or alloys thereof.

A first upper insulating layer 110b may be provided above the first core layer 111 to expose the first upper pads 110pb. The first upper insulating layer 110b may include, for example, solder resist. In some embodiments, the first upper insulating layer 110b may include an epoxy-based resin.

A first lower insulating layer 110a may be provided below the first core layer 111 to expose the first lower pads 110pa. The first lower insulating layer 110a may include, for example, solder resist. In some embodiments, the first lower insulating layer 110a may include an epoxy-based resin.

The at least one semiconductor chip 300 may be mounted on the first package substrate 100.

The at least one semiconductor chip 300 may include a logic semiconductor chip and/or a memory semiconductor chip. For example, the logic semiconductor chip may be an application processor (AP), a microprocessor, a central processing unit (CPU), a controller, a graphics processing unit (GPU), or an application specific integrated circuit (ASIC). Also, the memory semiconductor chip may be, for example, a volatile memory such as a dynamic random access memory (DRAM) or a static random access memory (SRAM), or a nonvolatile memory such as a phase-change random access memory (PRAM), a magneto-resistive random access memory (MRAM), a ferroelectric random access memory (FeRAM), or a resistive random access memory (RRAM).

The second package substrate 200 may be provided on the at least one semiconductor chip 300 including first and second semiconductor chips 310 and 320.

The second package substrate 200 may include a second redistribution layer 210, a second upper insulating layer 210b disposed above the second redistribution layer 210, and a second lower insulating layer 210a disposed below the second redistribution layer 210. Also, the second package substrate 200 may include second upper pads 210pb exposed by the second upper insulating layer 210b and second lower pads 210pa exposed by the second lower insulating layer 210a.

The second upper pads 210pb and the second lower pads 210pa may include a conductive material, for example, aluminum (Al), copper (Cu), nickel (Ni), cobalt (Co), zinc (Zn), gold (Au), silver (Ag), platinum (Pt), or alloys thereof.

The second redistribution layer 210 may include a second core layer 211, second redistribution lines 213 disposed on an upper surface and a lower surface of the second core layer 211 and/or inside the second core layer 211 and electrically connecting the second upper pads 210pb and the second lower pads 210pa to each other, a heat dissipation pattern 213h, and second conductive vias 215 electrically connecting the second redistribution lines 213 to each other.

The second core layer 211 may include at least one material selected from phenol resin, epoxy resin, and polyimide. For example, the second core layer 211 may include at least one material selected from FR-4, tetrafunctional epoxy, polyphenylene ether, epoxy/polyphenylene oxide, BT, THERMOUNT®, cyanate ester, polyimide, and liquid crystal polymer.

The second redistribution lines 213 may include a conductive material such as copper (Cu), aluminum (Al), silver (Ag), tin (Sn), gold (Au), nickel (Ni), lead (Pb), titanium (Ti), or alloys thereof. However, the material of the second redistribution lines 213 is not limited thereto, and the second redistribution lines 213 may include, for example, electrolytically deposited (ED) copper foil, rolled-annealed (RA) copper foil, stainless steel foil, aluminum foil, ultra-thin copper foils, sputtered copper, or copper-alloys.

The heat dissipation pattern 213h may include a conductive material, and may be provided to be insulated from the second redistribution lines 213. The heat dissipation pattern 213h may be formed of substantially the same material as the second redistribution lines 213 and may include, for example, a conductive material such as copper (Cu), aluminum (Al), silver (Ag), tin (Sn), gold (Au), nickel (Ni), lead (Pb), titanium (Ti), or alloys thereof. However, the material of the heat dissipation pattern 213h is not limited thereto, and may include ED copper foil, RA copper foil, stainless steel foil, aluminum foil, ultra-thin copper foil, sputtered copper, or copper alloys.

The second redistribution lines 213 may be disposed on an upper surface and a lower surface of the second core layer 211 and inside the second core layer 211. In example embodiments, the second redistribution lines 213 have been described as being formed in three levels, but example embodiments are not limited thereto. For example, the second redistribution lines 213 may be formed on only the upper and lower surfaces of the second core layer 211, or may be formed on four or more levels. In example embodiments, among the second redistribution lines 213 provided on three levels, upper redistribution lines provided on an uppermost level may extend from the upper surface of the second core layer 211. Among the second redistribution lines 213 provided on three levels, intermediate redistribution lines provided on an intermediate level may extend from the inside of the second core layer 211 in a direction, parallel or substantially parallel to the upper surface of the second core layer 211. Lower redistribution lines provided on a lowermost level may extend from the lower surface of the second core layer 211.

In some embodiments, at least a portion of the upper and lower redistribution lines may be appropriately distributed and provided to be connected to the second upper pads 210pb and the second lower pads 210pa.

The second conductive vias 215 are vias for connecting the second redistribution lines 213 in a vertical direction, and may be formed to penetrate through at least a portion of the second core layer 211. In some embodiments, the second conductive vias 215 may include a conductive material, for example a metal such as copper, nickel, stainless steel, molybdenum, manganese, cobalt, tin, magnesium, rhenium, beryllium, gallium, or ruthenium, or alloys thereof.

The heat dissipation pattern 213h may be connected to a heat dissipation via (for example, a second heat dissipation via 333) to be described later, serving to dissipate heat from a semiconductor device of a lower semiconductor chip. A connection relationship between the heat dissipation pattern 213h and the heat dissipation via will be described later.

At least a portion of the second redistribution lines 213 may be formed to be coplanar with the heat dissipation pattern 213h. For example, the second redistribution lines 213 may be provided on a plurality of levels within the second core layer 211 as described above, and the heat dissipation pattern 213h may be formed to be coplanar with the second redistribution lines 213, provided on the lowermost level, among the second redistribution lines provided on the plurality of levels. For example, the heat dissipation pattern 213h and the lowermost second redistribution lines 213 may be manufactured in the same process.

A second upper insulating layer 210b may be provided above the second core layer 211 to expose the second upper pads 210pb, and a second lower insulating layer 210a may be provided below the second core layer 211 to expose the second lower pads 210pa.

Each of the second upper insulating layer 210b and the second lower insulating layer 210a may include, for example, solder resist. In some embodiments, each of the second upper insulating layer 210b and the second lower insulating layer 210a may include an epoxy-based resin.

The second lower insulating layer 210a may have an opening OPN exposing not only a second lower pad 210pa but also a portion of the heat dissipation pattern 213h. The heat dissipation pattern 213h may be connected to a heat dissipation via to be described later through an opening OPN.

The at least one semiconductor chip 300 between the first package substrate 100 and the second package substrate 200 may be provided in plural.

In example embodiments, the semiconductor chip 300 may have at least one heat dissipation via disposed adjacent to a semiconductor device, serving as a heat source in the semiconductor chip 300, to be provided as a material having high thermal conductivity (e.g., relatively high thermal conductivity) and to dissipate heat of the semiconductor device. The heat dissipation via may be connected to the heat dissipation pattern 213h of the second package substrate 200 to dissipate heat. When a semiconductor chip is provided in plural, a heat dissipation via provided in an uppermost semiconductor chip may be connected to the heat dissipation pattern 213h of the second package substrate 200.

Example embodiments will be described below, in which the semiconductor chip 300 is provided in plural and includes a first semiconductor chip 310 and a second semiconductor chip 320 stacked in order. Accordingly, when a plurality of semiconductor chips are provided, the first semiconductor chip 310 may be a lowermost semiconductor chip or an intermediate semiconductor chip disposed between other semiconductor chips. In addition, when a plurality of semiconductor chips are provided, the second semiconductor chip 320 may correspond to a semiconductor chip provided in an uppermost level. For example, it will be appreciated that even when a larger number of semiconductor chips are stacked, a configuration may be modified based on the same concept.

In example embodiments, the first semiconductor chip 310 may include a first semiconductor substrate 311, a first semiconductor device layer 313 disposed on the first semiconductor substrate 311, and at least one heat dissipation via 331 penetrating through at least a portion of the first semiconductor chip 310.

In example embodiments, the first semiconductor device layer 313 may correspond to an active layer at which individual devices are formed, and may include various individual devices therein. For example, an active surface of the first semiconductor chip 310 may be a lower surface thereof.

The first semiconductor substrate 311 may be a silicon (Si) substrate. In example embodiments, a semiconductor substrate may include a semiconductor element such as germanium (Ge) or a compound semiconductor such as silicon carbide (SiC), gallium arsenide (GaAs), indium arsenide (InAs), or indium phosphide (InP).

The semiconductor devices, included in the first semiconductor device layer 313, may include various microelectronic devices, for example, complementary metal-insulator-semiconductor transistors (CMOS transistors), metal-oxide-semiconductor filed effect transistors (MOSFETs), system large scale integration (LSI), image sensors such as CMOS imaging sensors (CIS), micro-electro-mechanical systems (MEMS), active devices, or passive devices.

The first heat dissipation via 331 may be provided in the form of a through-via penetrating through at least a portion of the first semiconductor substrate 311. The first heat dissipation via 331 is a via for dissipating heat generated from a semiconductor device in the first semiconductor chip 310, and may be provided adjacent to the semiconductor device.

The first heat dissipation via 331 may include one of a material having high thermal conductivity to smoothly dissipate heat. The first heat dissipation via 331 may include, for example, aluminum (Al), tin (Sn), copper (Cu), gold (Au), molybdenum (Mo), cobalt (Co), titanium (Ti), tantalum (Ta), silver (Ag), nickel (Ni), aluminum oxide (Al₂O₃), zinc oxide (ZnO), silicon carbide (SiC), aluminum nitride (AlN), boron nitride (BN), alloys thereof, or combinations thereof. However, the material of the first heat dissipation via 331 is not limited thereto, and may be any material having high thermal conductivity, for example, a composition in which insulating inorganic particles are distributed in a polymer matrix. In some embodiments, the inorganic particle in the polymer matrix may be an oxide or a nitride of a metal or a metalloid. The polymer matrix may be, for example, epoxy resin, polyimide, polyester, polystyrene, polyethylene terephthalate, high-density polyethylene, low-density polyethylene, polyurethane, polybenzoxazine, polyvinylidene fluoride (PVdF), or the like, but example embodiments are not limited thereto. The insulating inorganic particles may be, for example, silica, silicon nitride, silicon carbide, alumina, titania, zirconia, ceria, aluminum nitride (AlN), boron nitride (BN), nanodiamond, or the like, but example embodiments are not limited thereto. The insulating inorganic particles may serve to increase the thermal conductivity of the heat dissipation via and may be, for example, any inorganic particles having thermal conductivity of 20 W/m·K (Watts per meter-Kelvin) or higher and improved mixing characteristics with the polymer matrix.

The first semiconductor chip 310 may include at least one signal via 340 penetrating through the first semiconductor substrate 311, and the first heat dissipation via 331 may be manufactured in a same process as the signal via 340. The first heat dissipation via 331 may be formed to have a diameter, larger than a diameter of the signal via 340, to have sufficient thermal conductivity.

In example embodiments, a first upper semiconductor insulating layer 310b and a first lower semiconductor insulating layer 310a may be respectively provided on an upper surface and a lower surface of the first semiconductor chip 310, and a first upper terminal pad(s) 310pb and a first lower terminal pad(s) 310pa exposed by the first upper semiconductor insulating layer 310b and the first lower semiconductor insulating layer 310a may also be included.

In example embodiments, a second semiconductor chip 320 may be disposed on the first semiconductor chip 310. The second semiconductor chip 320 may have a smaller size than the first semiconductor chip 310, but example embodiments are not limited thereto and the second semiconductor chip 320 may have a same size as the first semiconductor chip 310.

The second semiconductor chip 320 may include a second semiconductor substrate 321, a second semiconductor device layer 323 disposed above the second semiconductor substrate 321, and at least one second heat dissipation via 333 penetrating through at least a portion of the second semiconductor chip 320.

In example embodiments, similarly to the first semiconductor device layer 313, the second semiconductor device layer 323 may correspond to an active layer including individual devices. In example embodiments, an active surface of the second semiconductor chip 320 may be a lower surface thereof.

The second semiconductor substrate 321 may be a silicon (Si) substrate. In example embodiments, the semiconductor substrate 321 may include a semiconductor element such as germanium (Ge), or a compound semiconductor such as silicon carbide (SiC), gallium arsenide (GaAs), indium arsenide (InAs), or indium phosphide (InP).

The semiconductor devices, included in the second semiconductor device layer 323, may include various microelectronic devices, for example, complementary metal-insulator-semiconductor transistors (CMOS transistors), metal-oxide-semiconductor filed effect transistors (MOSFETs), system large scale integration (LSI), image sensors such as a CMOS imaging sensors (CISs), micro-electro-mechanical systems (MEMS), active devices, or passive devices. The semiconductor devices, provided at the first semiconductor device layer 313 and the second semiconductor device layer 323, may be homogeneous or heterogeneous.

The second heat dissipation via 333 may be provided in the form of a through-via penetrating through at least a portion of the second semiconductor substrate 321. The second heat dissipation via 333 is a via for dissipating heat generated from the second semiconductor device layer 323 in the second semiconductor chip 320. The second heat dissipation via 333 may be provided in a location, adjacent to the semiconductor device in the second semiconductor device layer 323, to dissipate heat from the semiconductor device.

Among the second heat dissipation via 333, a certain second heat dissipation via 333t may be separately connected to the first heat dissipation via 331 through a first upper terminal pad 310pb, a second connection terminal 430, and a second lower terminal pad 320pa to be provided to dissipate heat from the semiconductor device. For example, the first heat dissipation via 331 may be connected to the certain second heat dissipation via 333t through the second connection terminal 430, so that heat generated from the semiconductor device moves to an upper side through the first heat dissipation via 331 and the certain second heat dissipation via 333t, and then finally reaches a heat dissipation pad or heat dissipation pattern of the second package substrate 200.

The second heat dissipation via 333 may include one of a material having high thermal conductivity to smoothly dissipate heat. The second heat dissipation via 333 may include, for example, aluminum (Al), tin (Sn), copper (Cu), gold (Au), molybdenum (Mo), cobalt (Co), titanium (Ti), tantalum (Ta), silver (Ag), nickel (Ni), aluminum oxide (Al₂O₃), zinc oxide (ZnO), silicon carbide (SiC), aluminum nitride (AlN), boron nitride (BN), alloys thereof, or combinations thereof. However, the material of the first heat dissipation via 331 is not limited thereto, and may be any material having high thermal conductivity, for example, a composition in which insulating inorganic particles are distributed in a polymer matrix. In some embodiments, the inorganic particle in the polymer matrix may be an oxide or a nitride of a metal or a metalloid. The polymer matrix may be, for example, epoxy resin, polyimide, polyester, polystyrene, polyethylene terephthalate, high-density polyethylene, low-density polyethylene, polyurethane, polybenzoxazine, polyvinylidene fluoride (PVdF), or the like, but example embodiments are not limited thereto. The insulating inorganic particles may be, for example, silica, silicon nitride, silicon carbide, alumina, titania, zirconia, ceria, aluminum nitride (AlN), boron nitride (BN), nanodiamond, or the like, but example embodiments are not limited thereto. The insulating inorganic particles may serve to increase the thermal conductivity of the heat dissipation via and may be, for example, any inorganic particles having thermal conductivity of 20 W/m·K or higher and improved mixing characteristics with the polymer matrix.

Examples embodiments of the second heat dissipation via 333 will be described subsequently.

In example embodiments, a second lower semiconductor insulating layer 320a may be provided on a lower surface of the second semiconductor chip 320, and second lower terminal pads 320pa exposed by the second lower semiconductor insulating layer 320a may also be included. Although not illustrated, a semiconductor insulating layer may be provided on an upper surface of the first semiconductor chip 310.

The semiconductor package 10 according to example embodiments may be connected to an external device through external connection terminals 410 provided on a lower side of the first package substrate 100.

The first semiconductor chip 310 may be connected to the first package substrate 100 by first connection terminals 420. For example, the first upper pad 110pb of the first package substrate 100 and the first lower terminal pad 310pa of the first semiconductor chip 310 may be connected by the first connection terminal 420.

The second semiconductor chip 320 may be connected to the first semiconductor chip 310 by second connection terminals 430. For example, the first upper terminal pad 310pb of the first semiconductor chip 310 and the second lower terminal pad 320pa of the second semiconductor chip 320 may be connected by the second connection terminal 430.

The first package substrate 100 may be connected to the second package substrate 200 by a connection structure 440. For example, the first upper pad 110pb of the first package substrate 100 and the second lower pad 210pa of the second package substrate 200 may be connected by the connection structure 440. The connection structure 440 may connect the first redistribution layer 110 and the second redistribution layer 210 by the first upper pad 110pb of the first package substrate 100 and the second lower pad 210pa of the second package substrate 200.

The external connection terminal 410, the first connection terminal 420, the second connection terminal 430, and/or the connection structure 440 may be bumps or solder balls. In example embodiments, the first connection terminal 420, the second connection terminal 430, and/or the connection structure 440 may be conductor pillars.

In example embodiments, the first and second semiconductor chips 310 and 320 may be connected by a second connection terminal 430 such as a bump or a solder ball, but example embodiments are not limited thereto. For example, the first and second semiconductor chips 310 and 320 may be connected by direct bonding using copper (Cu-to-Cu direct bonding). When the first and second semiconductor chips 310 and 320 are directly connected to each other, a conductive bump may be absent between the first and second semiconductor chips 310 and 320. For example, the first and second semiconductor chips 310 and 320 may be directly connected to each other (Cu-to-Cu direct bonding) using a bonding pad.

In example embodiments, a molding layer 500 may be provided between the first package substrate 100 and the second package substrate 200. The molding layer 500 may include a polymer material such as an epoxy molding compound (EMC). However, example embodiments are not limited thereto, and the molding layer 500 may include various materials such as an epoxy-based material, a thermosetting material, a thermoplastic material, and an ultraviolet (UV)-treated material.

Although not illustrated, an underfill material layer may be provided in a space between the first semiconductor chip 310 and the first package substrate 100 to surround the second connection terminals 430, in a space between the first package substrate 100 and the second package substrate 200. The underfill material layer may include, for example, an epoxy resin formed in a capillary underfill manner. In some embodiments, the underfill material layer may be a non-conductive film (NCF).

Hereinafter, heat dissipation structures including a second heat dissipation via will be described in detail with reference to the drawings.

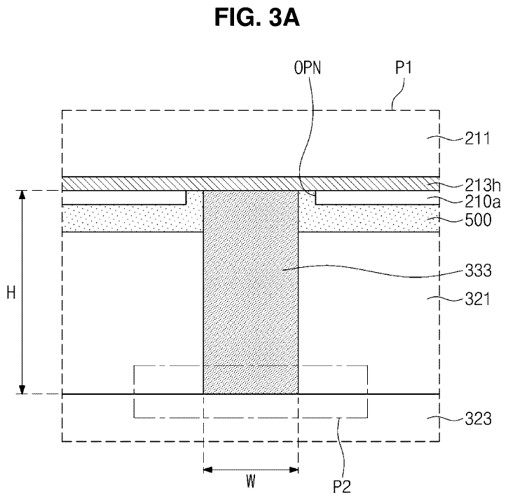

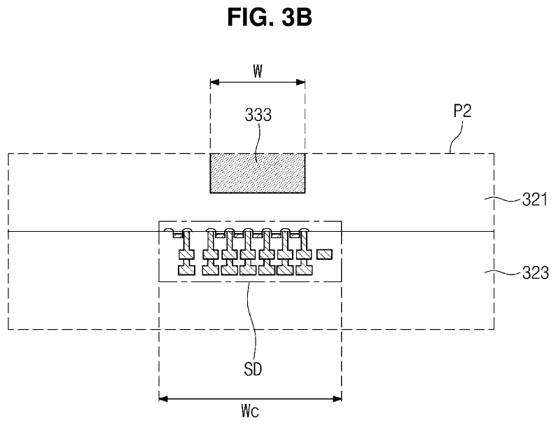

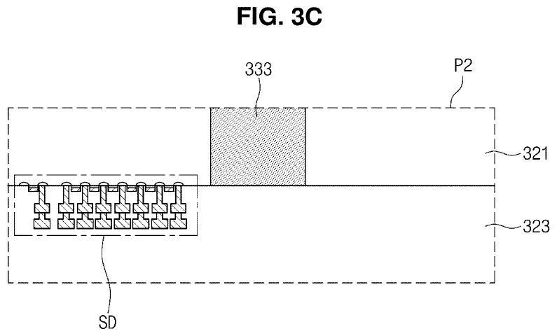

FIG. 3A is an enlarged cross-sectional view of portion P1 of FIG. 2, and FIGS. 3B and 3C are enlarged cross-sectional views of portion P2 of FIG. 3A.

Referring to FIGS. 3A to 3C, the second heat dissipation via 333 may be formed through at least a portion of the second semiconductor substrate 321.

For example, the second heat dissipation via 333 may be formed to a location, adjacent to a semiconductor device SD of the semiconductor device layer 323, through a portion of the second semiconductor substrate 321 as illustrated in FIG. 3B, or may be formed through an entirety of the second semiconductor substrate 321 as illustrated in FIG. 3C.

In example embodiments, the second heat dissipation via 333 may be disposed adjacent to the semiconductor device SD within a range of electrical insulation from the semiconductor device SD to effectively move heat generated from the semiconductor device SD. For example, when viewed in plan view, the second heat dissipation via 333 may be disposed to overlap the semiconductor device SD of the second semiconductor device layer 323 as illustrated in FIG. 3B, or may be disposed in a location adjacent to the semiconductor device SD along a direction parallel or substantially parallel to a surface of the second semiconductor device layer 323 as illustrated in FIG. 3C so that the second heat dissipation via 333 may not overlap the semiconductor device SD of the second semiconductor device layer 323 when viewed in plan view.

The semiconductor device SD, included in the second semiconductor device layer 323, may be provided as various individual devices such as, for example, CMOS transistors, MOSFETs, system LSIs, and CISs. Such semiconductor devices SD may serve as a heating source at the time of driving. In FIGS. 3B and 3C, a plurality of transistors and signal lines are illustrated as being formed as an example of the semiconductor device SD. However, the semiconductor device SD is not limited thereto, and the semiconductor device SD may be any wiring or circuit serving as a heating source.

In example embodiments, the second heat dissipation via 333 may be provided as close as possible to the semiconductor device SD, a heating source, to dissipate heat from the heating source through the second heat dissipation via 333. To this end, in example embodiments, the second heat dissipation via 333 may protrude from the upper surface of the second semiconductor substrate 321, and an upper surface of the protruding second heat dissipation via 333 may be in direct contact with a lower surface of the heat dissipation pattern 213h in the second package substrate 200. The second lower insulating layer 210a of the second package substrate 200 may have an opening OPN through which a portion of the heat dissipation pattern 213h is exposed, and an upper surface of the second heat dissipation via 333 and a lower surface of the heat dissipation pattern 213h may be in contact with each other in a region in which the opening OPN is formed.

As a result, heat generated from the semiconductor device SD of the second semiconductor device layer 323 may be dissipated to the heat dissipation pattern 213h of the second package substrate 200 through the second heat dissipation via 333.

In example embodiments, the second heat dissipation via 333 may be manufactured by forming a trench in a direction from the upper surface to the lower surface of the second semiconductor substrate 321 and then filling the trench with a conductive material. As illustrated in FIG. 3C, when the second heat dissipation via 333 is formed through the entirety of the second semiconductor substrate 321, the second heat dissipation via 333 may be manufactured by forming a trench in a direction from the upper surface to the lower surface of the second semiconductor substrate 321 or in a direction from the lower surface to the upper surface of the second semiconductor substrate 321 and then filling the trench with a conductive material. In the second heat dissipation via 333, a portion protruding from the upper surface of the second semiconductor substrate 321 may be formed through deposition and patterning, plating, or the like, to be in contact with the heat dissipation pattern 213h.

In example embodiments, the heat, generated from the semiconductor device SD of the first semiconductor device layer 313, may be dissipated to the heat dissipation pattern 213h of the second package substrate 200 through the first heat dissipation via 331 and the second heat dissipation via 333.

Although not illustrated, the first heat dissipation via 331 may also be provided in the same shape as the second heat dissipation via 333. For example, the first heat dissipation via 331 may be formed through a portion of the first semiconductor substrate 311 to a location adjacent to the semiconductor device SD of the first semiconductor device layer 313, similarly to what is illustrated in FIG. 3B. Alternatively, the first heat dissipation via 331 may be formed through the entirety of the first semiconductor substrate 311, similarly as to what is illustrated in FIG. 3C. In example embodiments, when viewed in plan view, the first heat dissipation via 331 may be disposed to overlap the semiconductor device SD of the first semiconductor device layer 313, or may be disposed adjacent to the semiconductor device SD along a direction parallel or substantially parallel to a surface of the first semiconductor device layer 313 similar to what is illustrated in FIG. 3C so that the first heat dissipation via 331 may not overlap the semiconductor device SD of the first semiconductor device layer 313 when viewed in plan. The first heat dissipation via 331 may be disposed as close as possible to significantly increase thermal conductivity within a range of electrical insulation from the semiconductor device SD.

A portion or some of the second heat dissipation vias 333 may be connected to the first heat dissipation vias 331 through the second connection terminal 430, rather than to the semiconductor devices SD of the second semiconductor device layer 323. For example, a portion or some of the second heat dissipation vias 333 may be connected to the semiconductor devices SD of the second semiconductor device layer 323, and another portion or some other of the second heat dissipation vias 333 may be connected to the first heat dissipation vias 331 through the second connection terminals 430. As a result, heat generated by the semiconductor devices SD of the first semiconductor device layer 313 and the second semiconductor device layer 323 may be effectively dissipated to the heat dissipation pattern 213h of the second package substrate 200.

In example embodiments, the first heat dissipation via 331 and/or the second heat dissipation via 333 may have a column shape having a composition diameter and height. For example, the first heat dissipation via 331 and/or the second heat dissipation via 333 may be provided to have a height which is at least about 8 times greater than a diameter thereof.

In example embodiments, the diameter of the first heat dissipation via 331 and/or the second heat dissipation via 333 may be about 20% or more to about 100% or less of the diameter of the semiconductor device SD, a heating source. In addition, the first heat dissipation via 331 and/or the second heat dissipation via 333 may have about 20% or more to 100% or less of the area of the semiconductor device SD. However, the area of the first heat dissipation via 331 and/or the second heat dissipation via 333 is not limited thereto and may be provided to be larger than the semiconductor device SD, as necessary.

In example embodiments, the diameter of the first heat dissipation via 331 and/or the second heat dissipation via 333 may be greater than that of the signal via 340.

In example embodiments, the heat dissipation structure may be modified in various forms to efficiently transfer heat. For example, the second heat dissipation via 333 and the heat dissipation pattern 213h may be modified in various forms.

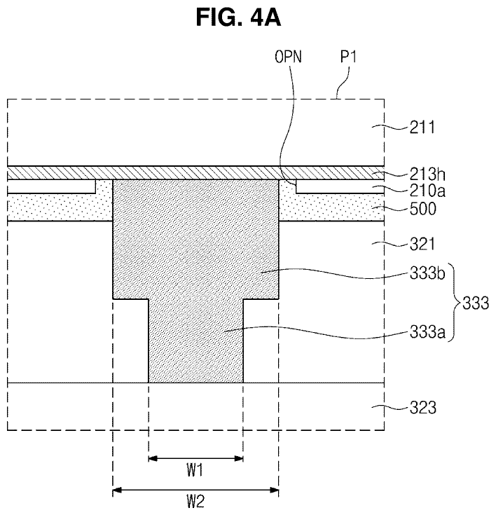

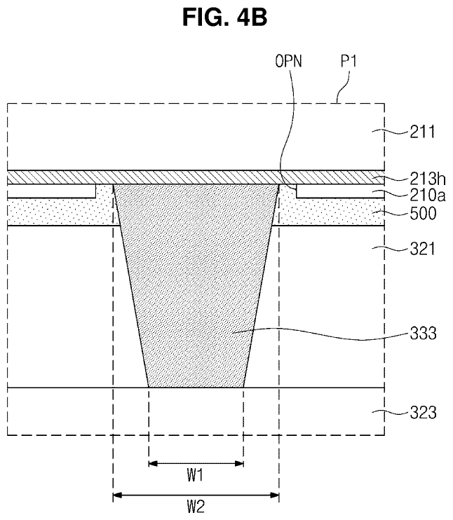

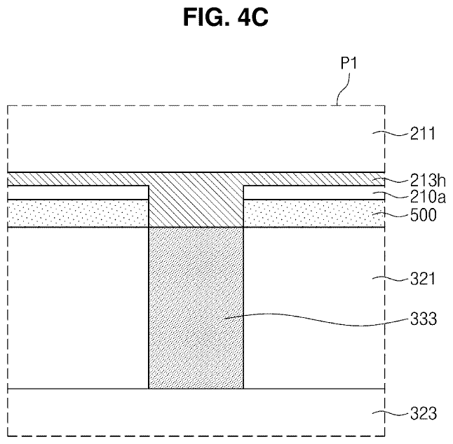

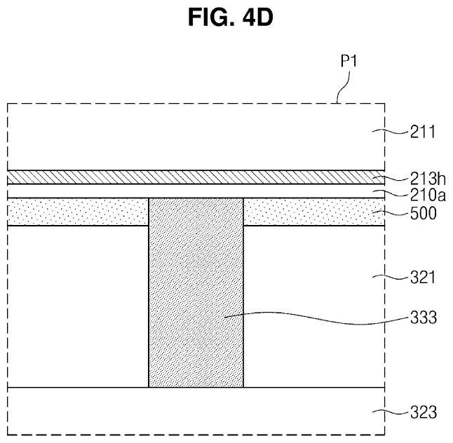

FIGS. 4A to 4D are cross-sectional views corresponding to portion P2 of FIG. 3A and illustrating heat dissipation structures according to example embodiments.

Referring to FIG. 4A, the second heat dissipation via 333 according to example embodiments may include a lower heat dissipation via 333a having a first diameter W1 and an upper heat dissipation via 333b having a second diameter W2. The first diameter W1 may be smaller than the second diameter W2, and the upper heat dissipation via 333b has a larger area than the lower heat dissipation via 333a. The upper heat dissipation via 333b has a greater diameter and a larger area than the lower heat dissipation via 333a, so that a contact area between an upper surface of the upper heat dissipation via 333b and the heat dissipation pattern 213h may be increased to facilitate heat transfer in an upward direction.

Referring to FIG. 4B, the second heat dissipation via 333 according to example embodiments may include a lower surface in contact with the second semiconductor device layer 323 and that has a first diameter W1, and an upper surface in contact with the heat dissipation pattern 213h and that has a second diameter W2. The first diameter W1 may be smaller than the second diameter W2. The diameter of the second heat dissipation via 333 may gradually increase from the lower surface to the upper surface. An area of the second heat dissipation via 333 at the upper surface is larger than an area of the second heat dissipation via 333 at the lower surface, so that a contact area between an upper surface of the upper heat dissipation via 333 and the heat dissipation pattern 213h may be increased to facilitate heat transfer in an upward direction.

Referring to FIG. 4C, in the heat dissipation structure according to example embodiments, the heat dissipation pattern 213h may be formed to have a different shape. For example, the heat dissipation pattern 213h may have a projection protruding in a downward direction, and the projection may protrude toward a portion exposed by the second lower insulating layer 210a of the second package substrate 200. For example, a surface of the second heat dissipation pattern 213h may be coplanar with an upper surface of the second semiconductor substrate 321. A lower surface of the projection may be in contact with the second heat dissipation via 333, and thus the second heat dissipation via 333 and the heat dissipation pattern 213h may be connected to each other.

The protruding heat dissipation pattern 213h may be formed by forming an opening OPN in the second lower insulating layer 210a and forming the opening OPN through various methods such as plating.

Referring to FIG. 4D, in the heat dissipation structure, at least a portion of the second heat dissipation vias 333 may protrude from the upper surface of the second semiconductor substrate 321 to be in contact with the molding layer 500, rather than with the heat dissipation pattern 213h. Heat may be dissipated through the contact between the second heat dissipation via 333 itself, penetrating through the second semiconductor substrate 321, and the molding layer 500 to dissipate the heat from the semiconductor device.

In example embodiments, the heat dissipation pattern 213h may be provided with a relatively large area to effectively dissipate heat from semiconductor devices through the first heat dissipation via 331 and/or the second heat dissipation via 333. When viewed in plan view, the heat dissipation pattern 213h may be provided on a region in which the first and second semiconductor chips 310 and 320 are provided. In the second package substrate 200, when viewed in plan view, the second lower pads 210pa and a portion of the second redistribution lines 213 may be provided outside of the first and second semiconductor chips 310 and 320 to be connected to the connection structure 440. Accordingly, the second redistribution lines 213 may not be provided in the overlapping region in which the first and second semiconductor chips 310 and 320 are provided, and the heat dissipation pattern 213h may be provided in the overlapping region.

In example embodiments, the heat dissipation pattern 213h may be provided in various shapes and numbers.

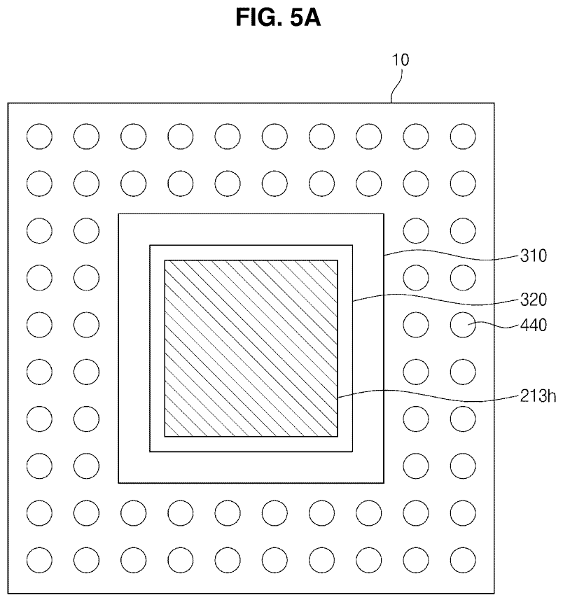

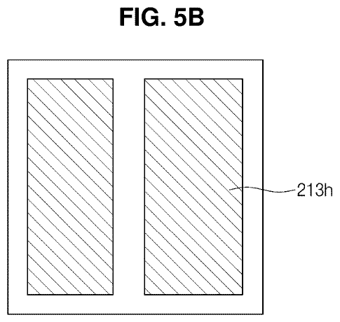

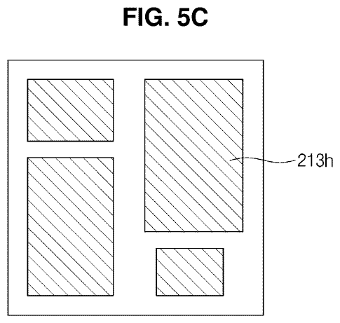

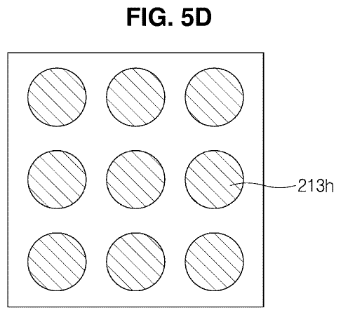

FIGS. 5A to 5D are plan views illustrating a heat dissipation pattern according to example embodiments, and FIG. 5A illustrates the heat dissipation patterns together with other components and FIGS. 5B to 5D illustrate only the heat dissipation pattern 213h.

As illustrated in FIG. 5A, the heat dissipation pattern 213h may be provided as a single pattern having a shape, similar to a shape of the second semiconductor device layer 323. As illustrated in FIGS. 5B to 5D, the heat dissipation pattern 213h may be provided as a plurality of patterns having various shapes. In example embodiments as shown in FIG. 5B, the heat dissipation pattern 213h is provided as having two patterns of rectangular shape next to each other. In example embodiments as shown in FIG. 5C, the heat dissipation pattern 213h is provided as having four patterns of rectangular shape and different size next to each other. In example embodiments as shown in FIG. 5D, the heat dissipation pattern 213h is provided as having a plurality of patterns of circular shape next to each other.

The shape and number of the heat dissipation patterns 213h may be determined in consideration of the locations or number of the second heat dissipation vias 333, and a single second heat dissipation via 333 may be connected to a single heat dissipation pattern 213h, or a plurality of second heat dissipation vias 333 may be connected to a single heat dissipation pattern 213h.

A semiconductor package having the above-described heat dissipation structure may allow heat, generated in a semiconductor chip, to be effectively dissipated through a heat dissipation structure including a heat dissipation via and a heat dissipation pattern. Accordingly, heat dissipation characteristics of the semiconductor package may be optimized. For example, in a semiconductor package according to example embodiments, a heat dissipation pattern including a material having high thermal conductivity may be provided in a second package substrate, and a heat dissipation via including a material having high thermal conductivity may be provided in each semiconductor chip and may be connected to the heat dissipation pattern to serve as a heat dissipation path. As a result, heat generated from a semiconductor device may be rapidly diffused to the outside to improve a heat dissipation function of the semiconductor package.

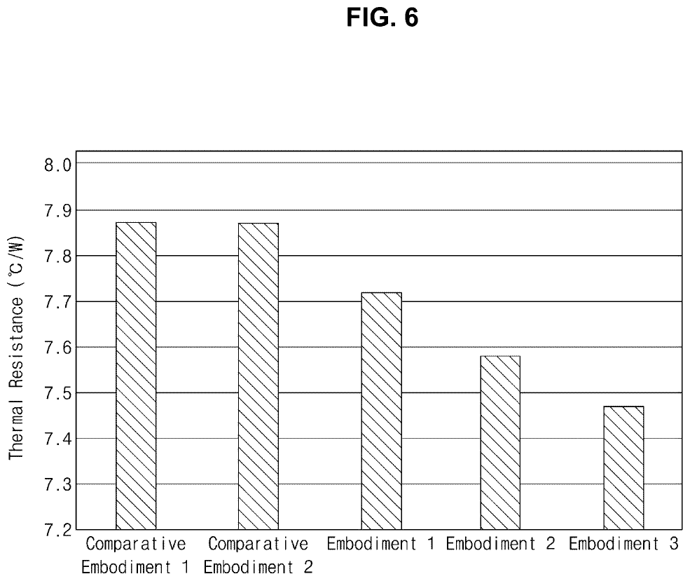

FIG. 6 is a simulation graph illustrating thermal resistance in a semiconductor package according to the related art and thermal resistance in a semiconductor package according to example embodiments of the inventive concepts. In FIG. 6, Comparative Example 1, Comparative Example 2, and Embodiments 1 to 3 illustrate thermal resistances when only a heat dissipation structure is changed in the state in which all conductions are the same, except for the heat dissipation structure. Comparative Example 1 and Comparative Example 2 illustrate thermal resistances in the semiconductor package according to the related art. Comparative Example 1 is an example in which a heat dissipation via is absent, and Comparative Example 2 is an example in which a heat dissipation via is present but is provided only inside a semiconductor chip. Embodiment 1 is an embodiment when a heat dissipation via is provided, and the other end of the heat dissipation via protrudes toward a molding layer to be in contact with the molding layer and, simultaneously, to be in contact with a lower insulating layer of the second package substrate, Embodiment 2 is an embodiment in which the other end of the heat dissipation via protrudes toward the second package substrate to be in contact with the heat dissipation pattern and both upper and lower portions thereof have desired (and/or alternatively predetermined) diameters, and Embodiment 3 is an embodiment in which the other end of the heat dissipation via is in contact with the heat dissipation pattern, and a diameter of an upper side is greater than a diameter of a lower side.

Referring to FIG. 6, in Comparative Examples 1 and 2, thermal resistance exhibited a significantly high value of 7.8 or more. However, Embodiment 1 had a thermal resistance reduction effect of about 2%, and Embodiment 2 had a thermal resistance reduction effect of about 4%. In particular, it was identified that Embodiment 3 had a thermal resistance reduction effect of about 5%.

A semiconductor package according to example embodiments has such a heat dissipation structure to improve thermal characteristics of the entire semiconductor package.

For example, semiconductor packages according to example embodiments may correspond to a lower semiconductor package or an upper semiconductor package constituting a package-on-package (POP) type semiconductor package. The semiconductor package according to example embodiments has such a heat dissipation structure, so that heat generated from a semiconductor chip in each semiconductor package may not affect adjacent semiconductor packages. As a result, thermal characteristics of the entire semiconductor package may be improved.

In addition, heat dissipation characteristics are improved, so that a function of a semiconductor device does not need to be limited. Thus, performance of the semiconductor package may be improved. In the related arts in which it is difficult to dissipate heat, by decreasing an operating frequency and a voltage of semiconductor devices in a semiconductor package, performance was limited to reduce heat. In the case in which heat dissipation performance is improved as in example embodiments, performance of semiconductor devices does not need to be limited. Accordingly, performance of final semiconductor packages may also be improved according to embodiments of the inventive concepts.

In addition, in the case of a logic semiconductor chip such as an application processor (AP), it has become important in recent years to provide heat dissipation characteristics of rapidly dissipating heat to improve operation speed and performance. Accordingly, semiconductor packages according to example embodiments of the inventive concepts may be applied to a semiconductor package, in which heat dissipation characteristics are important, to optimize heat dissipation characteristics, and thus may significantly contribute to improving operation speed and performance of the semiconductor package.

In the above-described example embodiments, the second heat dissipation vias are illustrated as being directly connected to the heat dissipation pattern, but example embodiments are not limited thereto.

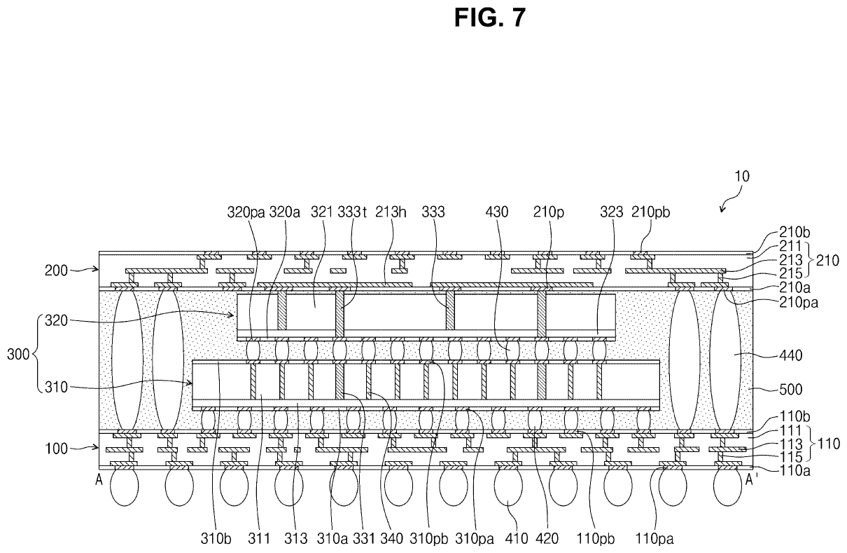

FIG. 7 is a cross-sectional view illustrating a second heat dissipation via 333 connected to a second lower pad 210pa of a second package substrate 200, in a semiconductor package according to example embodiments of the inventive concepts.

Referring to FIG. 7, the second lower pads 210pa may be provided on a heat dissipation pattern 213h of the second package substrate 200. For example, an upper surface of the second heat dissipation via 333 may be in contact with a lower surface of the second lower pads 210p. A diameter or an area of the second lower pad 210p may be greater than or equal to a diameter or an area of an upper surface of the second heat dissipation via 333 to be in sufficient contact with the top surface of the second heat dissipation via 333. The second lower pads 210p of the second package substrate 200 in contact with the heat dissipation pattern 213h may be formed in the same process as the second lower pads 210pa connected to a connection structure 440.

In FIG. 7, a semiconductor chip is illustrated as being provided in plural, but example embodiments are not limited thereto.

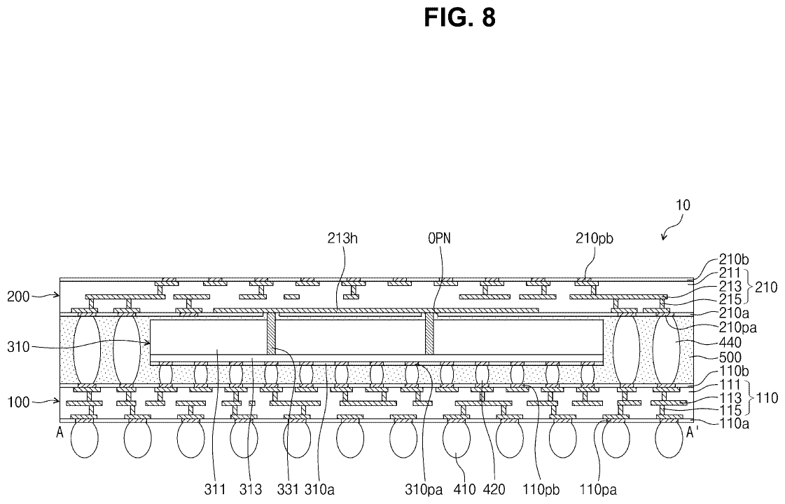

FIG. 8 is a cross-sectional view of a semiconductor package according to example embodiments of the inventive concepts, and illustrates a single semiconductor chip present between a first package substrate 100 and a second package substrate 200.

Referring to FIG. 8, a semiconductor chip 310 may include a semiconductor substrate 311, a semiconductor device layer 313 disposed on the semiconductor substrate 311, and at least one heat dissipation via 331 penetrating through at least a portion of the semiconductor chip 310.

In example embodiments, since a semiconductor chip is not stacked on other semiconductor chips, a signal via penetrating through a semiconductor substrate to transmit a signal to stacked semiconductor chips may not be provided, and a structure of a heat dissipation via may be substantially the same as the structure in the above-described embodiments.

The semiconductor package according to the present embodiment may be provided as a package-on-package (POP) type package.

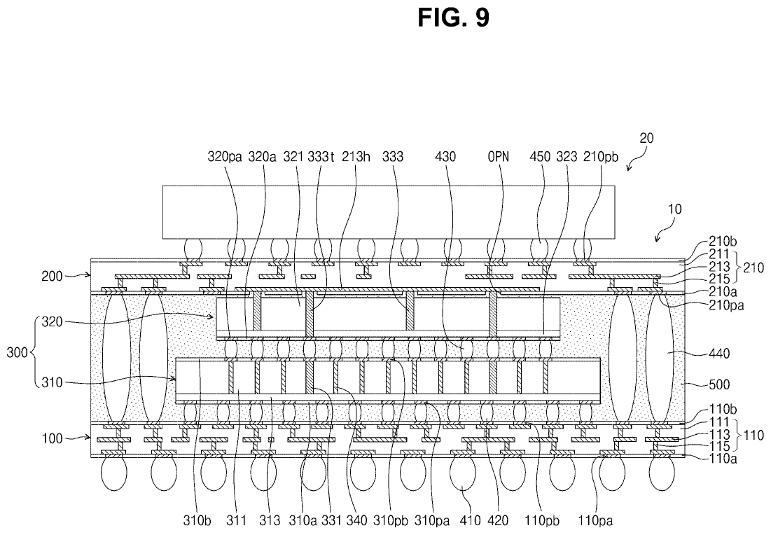

FIG. 9 is a cross-sectional view of a package-on-package (POP) type package according to example embodiments.

Referring to FIG. 9, a POP type package may include a first semiconductor package 10 and a second semiconductor package 20 disposed on the first semiconductor package 10.

The first semiconductor package 10 may include a first package substrate 100, at least one semiconductor chip 300 mounted on the first package substrate 100, and a second package substrate 200, and may be for example the package according to example embodiments described in FIGS. 1 and 2.

The second semiconductor package 20 may be a semiconductor device, among a variety of semiconductor devices. For example, the second semiconductor package 20 may be a logic chip such as a central processing unit (CPU) chip, a graphics processing unit (GPU) chip, or an application processor (AP) chip. In example embodiments, the second semiconductor package 20 may include, for example, a dynamic random access memory (DRAM) chip, a static random access memory (SRAM) chip, a flash memory chip, an electrically erasable and programmable read-only memory (EEPROM) chip, a phase-change random access memory (PRAM) chips, a magnetic random access memory (MRAM) chip, or a resistive random access memory (RRAM) chip.

The second semiconductor package 20 may include a single semiconductor chip, or may have a structure in which a plurality of semiconductor chips, or the like, are stacked.

When the second semiconductor package 20 includes a single chip, a semiconductor device may be formed on an active surface of a semiconductor substrate.

When the second semiconductor package 20 has a structure in which a plurality of semiconductor chips are stacked, the semiconductor package may include an additional package substrate, and the plurality of semiconductor chips may be mounted on the package substrate. In this case, the package substrate may be referred to as an interposer.

The second semiconductor package 20 may be connected to the second package substrate 200 of the first package through third connection terminals 450. The third connection terminals 450 may be a bump or a solder ball.

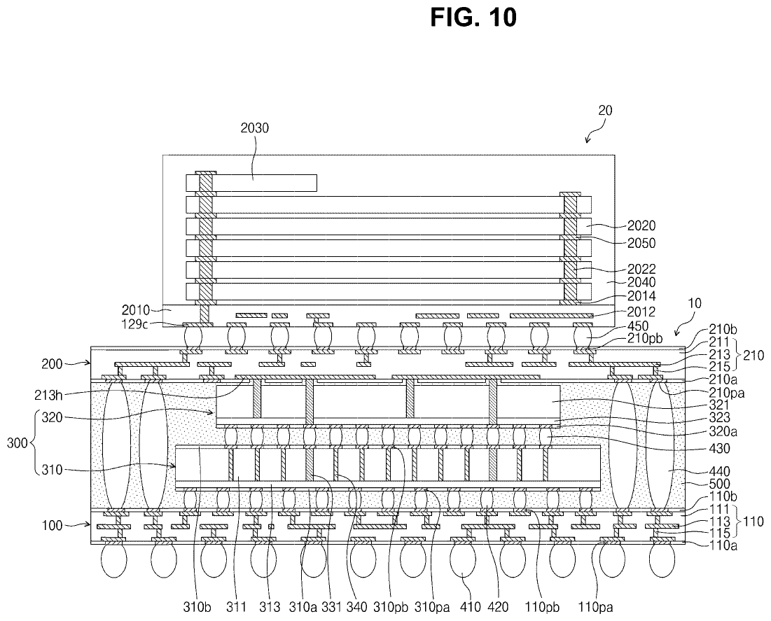

FIG. 10 is a cross-section view illustrating an example of the second semiconductor package.

Referring to FIG. 10, a second semiconductor package 20 may include a plurality of semiconductor chips 2020 sequentially stacked on a third package substrate 2010. A memory control chip 2030 may be connected to the plurality of semiconductor chips 2020. A stack structure of the plurality of semiconductor chips 2020 and the memory control chip 2030 may be encapsulated on a third package substrate 2010 with an encapsulant 2040 such as a thermosetting resin.

FIG. 10 illustrates a structure in which five semiconductor chips 2020 are vertically stacked, but the number and a stacked direction of the semiconductor chips 2020 are not limited thereto. The number of the semiconductor chips 2020 may be more than five or less than five, as necessary or desired. The plurality of semiconductor chips 2020 may be horizontally arranged on the third package substrate 2010 or may be arranged in a connection structure in which vertical mounting and horizontal mounting are combined with each other. In example embodiments, the memory control chip 2030 may be omitted.

The third package substrate 2010 may be a flexible printed circuit board, a rigid printed circuit board, or a combination thereof. The third package substrate 2010 may include a substrate internal wiring 2012 and a connection terminal 2014. The connection terminal 2014 may be formed on one surface of the third package substrate 2010. A third connection terminal 129c may be formed on the other surface of the third package substrate 2010. The connection terminal 2014 may be electrically connected to the third connection terminal 129c through the substrate internal wiring 2012.

In example embodiments, the second semiconductor package 20 may include via structure units 2022. The via structure units 2022 may be electrically connected to the connection terminal 2014 of the third package substrate 2010 by a connection member 2050 such a bump. In example embodiments, the via structure unit 2022 may be omitted from the memory control chip 2030.

Each of the plurality of semiconductor chips 2020 may include system LSI, DRAM, SRAM, EEPSRAM, EEPROM, PRAM, MRAM, or RRAM. The memory control chip 2030 may include logic circuits such as, for example, a serializer/deserializer (SER/DES) circuit.

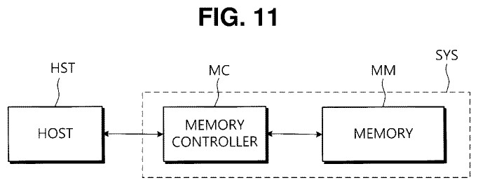

FIG. 11 is a block diagram illustrating an electronic system according to example embodiments of the inventive concepts.

An electronic system SYS may include a memory MM and a memory controller MC. The memory controller MC may control the memory MM to read data from the memory MM and/or write data in the memory MM in response to a request from a host HST. In example embodiments, the memory controller MC may be the first semiconductor package 10 described with reference to FIG. 10, and the memory MM may be the second semiconductor package 20 described with reference to FIG. 10.

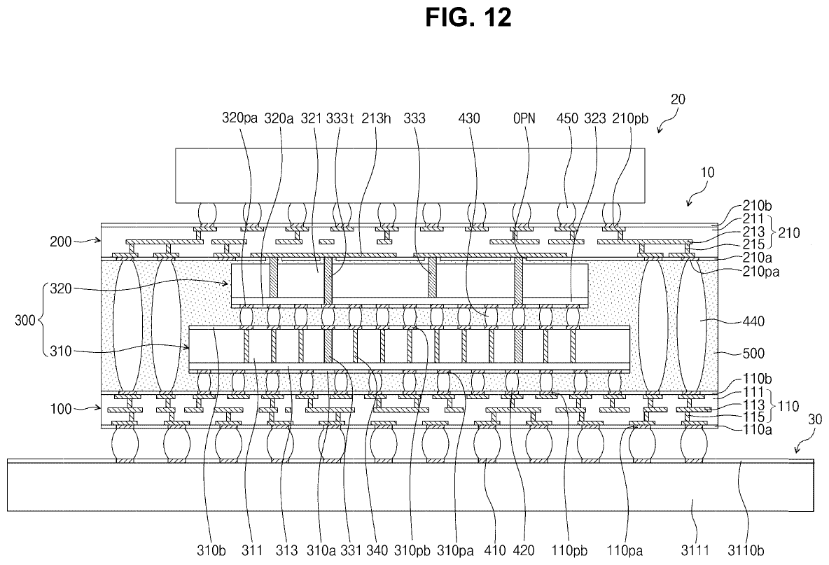

FIG. 12 is a cross-sectional view illustrating a portion of an electronic system in detail.

Referring to FIGS. 11 and 12, the electronic system SYS may include a mainboard 30 of the host HST and a POP package mounted on the mainboard 30. The POP package has been described with reference to FIG. 10, and thus redundant descriptions will be omitted.

The mainboard 30 may include a mainboard core layer 3111 and a mainboard insulator layer 3110b covering an upper surface of the mainboard core layer 3111. The mainboard core layer 3111 may include at least one material selected from phenol resin, epoxy resin, and polyimide. The mainboard core layer 3111 may include at least one material selected from, for example, FR-4, tetrafunctional epoxy, polyphenylene ether, epoxy/polyphenylene oxide, BT, THERMOUNT®, cyanate ester, polyimide, and liquid crystal polymer.

The main board insulator layer 3110b may include, for example, solder resist. In some embodiments, the mainboard insulator layer 3110b may include epoxy-based resin.

As set forth above, according to example embodiments, a semiconductor package having a heat dissipation structure is provided. The semiconductor package may effectively dissipate heat, generated in a semiconductor chip, through the heat dissipation structure to improve performance and reliability of the semiconductor package.

While example embodiments have been shown and described above, it will be apparent to those skilled in the art that modifications and variations could be made without departing from the scope of the present inventive concepts as defined by the appended claims.

What is claimed is:

1. A semiconductor package comprising:
a first package substrate comprising a first redistribution layer;
at least one semiconductor chip on the first redistribution layer and comprising a semiconductor device; and
a second package substrate on the at least one semiconductor chip and comprising a second redistribution layer,
wherein the at least one semiconductor chip comprises at least one heat dissipation via configured as a dissipation path of heat generated from the semiconductor device, and
the at least one heat dissipation via having one end adjacent to the semiconductor device and penetrating through at least a portion of the at least one semiconductor chip, and another end contacting the second package substrate.

2. The semiconductor package of claim 1, further comprising: a molding layer between the first package substrate and the second package substrate to surround the at least one semiconductor chip,
wherein the another end of the heat dissipation via contacts the molding layer.

3. The semiconductor package of claim 1, wherein the another end of the at least one heat dissipation via is connected to the second redistribution layer.

4. The semiconductor package of claim 3, further comprising:
a first connection terminal between the at least one semiconductor chip and the first redistribution layer and connecting the at least one semiconductor chip and the first redistribution layer to each other; and
at least one connection structure connecting the first redistribution layer and the second redistribution layer to each other.

5. The semiconductor package of claim 4, wherein the second redistribution layer comprises:
redistribution lines connected to the at least one connection structure; and
a heat dissipation pattern insulated from the redistribution lines, and
the at least one heat dissipation via is connected to the heat dissipation pattern.

6. The semiconductor package of claim 5, wherein the at least one heat dissipation via has an upper surface directly contacting a lower surface of the heat dissipation pattern.

7. The semiconductor package of claim 6, wherein at least a portion of the redistribution lines are coplanar with the heat dissipation pattern.

8. The semiconductor package of claim 6, wherein the at least one semiconductor chip further comprises a semiconductor substrate on which the semiconductor device is mounted, and the at least one heat dissipation via penetrates through at least a portion of the semiconductor substrate when viewed in plan view.

9. The semiconductor package of claim 8, wherein the at least one heat dissipation via is in a location adjacent to the semiconductor device, or disposed to overlap the semiconductor device when viewed in plan view.

10. The semiconductor package of claim 9, wherein an area of the at least one heat dissipation via is 20% or more of an area of the semiconductor device when viewed in plan view.

11. The semiconductor package of claim 6, wherein an upper diameter of the at least one heat dissipation via is greater than a lower diameter of the at least one heat dissipation via when viewed in plan view.

12. The semiconductor package of claim 6, wherein the at least one heat dissipation via comprises:
a lower via having a first diameter; and
an upper via having a second diameter, greater than the first diameter.

13. The semiconductor package of claim 4, wherein the at least one semiconductor chip comprises:
a first semiconductor chip disposed on the first redistribution layer; and
a second semiconductor chip disposed on the first semiconductor chip.

14. The semiconductor package of claim 13, wherein the first semiconductor chip comprises a through-via penetrating through at least a portion of the first semiconductor chip, and a first heat dissipation via from among the at least one heat dissipation via penetrating through at least a portion of the first semiconductor chip, and
the second semiconductor chip comprises a second heat dissipation via from among the at least one heat dissipation via penetrating through the second semiconductor chip and having one end connected to the first heat dissipation via and another end connected to the second redistribution layer.

15. The semiconductor package of claim 14, wherein the first semiconductor chip comprises a first semiconductor substrate and a first semiconductor device provided on the first semiconductor substrate, and the second semiconductor chip comprises a second semiconductor substrate and a second semiconductor device provided on the second semiconductor substrate, and
the through-via and the first heat dissipation via penetrate through the first semiconductor substrate, and the second heat dissipation via penetrates through the second semiconductor substrate.

16. The semiconductor package of claim 14, wherein a cross-sectional view of at least one of the first heat dissipation via or the second heat dissipation via is larger than a cross-sectional area of the through-via.

17. The semiconductor package of claim 16, wherein a height of the at least one of the first heat dissipation via or the second heat dissipation via is at least 8 times greater than a diameter of the at least one of the first heat dissipation via and the second heat dissipation via.

18. A package-on-package type semiconductor package comprising a first semiconductor package and a second semiconductor package stacked in order, wherein at least one of the first semiconductor package and the second semiconductor package comprises:
a first package substrate comprising a first redistribution layer;
at least one semiconductor chip on the first redistribution layer;
a first connection terminal between the at least one semiconductor chip and the first redistribution layer and connecting the at least one semiconductor chip and the first redistribution layer;
a second package substrate on the at least one semiconductor chip and comprising a second redistribution layer; and
at least one connection structure connecting the first redistribution layer and the second redistribution layer to each other, and
the at least one semiconductor chip comprises at least one heat dissipation via penetrating through at least a portion of the at least one semiconductor chip and connected to the second redistribution layer.

19. The package-on-package type semiconductor package of claim 18, wherein the at least one heat dissipation via has one end connected to the second redistribution layer and another end adjacent to a semiconductor device within the at least one semiconductor chip.

20. An electronic system comprising a mainboard and a semiconductor package mounted on the mainboard, wherein the semiconductor package comprises:
a first package substrate comprising a first redistribution layer;
at least one semiconductor chip on the first redistribution layer and comprising a semiconductor device; and
a second package substrate on the at least one semiconductor chip and comprising a second redistribution layer, and
the semiconductor chip comprises at least one heat dissipation via configured as a heat dissipation path of heat generated from the semiconductor device,
the at least one heat dissipation via having one end adjacent to the semiconductor device and penetrating through at least a portion of the at least one semiconductor chip, and another end contacting the second package substrate.
